(19) United States
(12) Patent Application Publication
(10) Pub. No.: US 2024/0274639 A1
(43) Pub. Date: Aug. 15, 2024

(54) ELECTRONIC DEVICE

(71) Applicant: InnoCare Optoelectronics Corporation, Tainan City (TW)

(72) Inventor: Yu-Heing Chen, Tainan City (TW)

(73) Assignee: InnoCare Optoelectronics Corporation, Tainan City (TW)

(21) Appl. No.: 18/403,672

(22) Filed: Jan. 3, 2024

Related U.S. Application Data
(60) Provisional application No. 63/446,010, filed on Feb. 15, 2023.

(30) Foreign Application Priority Data
Nov. 1, 2023 (TW) 112141904

(51) Int. Cl. H01L 27/146

(52) U.S. Cl. CPC H01L 27/14636; H01L 27/14603; H01L 27/14663

(57) ABSTRACT

An electronic device configured to detect an object to be detected includes at least one light source and a plurality of sensors. The at least one light source is arranged on a first plane and illuminates the object to be detected. The plurality of sensors are arranged on a second plane and surround the object to be detected. The plurality of sensors are stitched together. The first plane is different from the second plane.

### CROSS-REFERENCE TO RELATED APPLICATION

This application claims the priority benefits of U.S. provisional application Ser. No. 63/446,010, filed on Feb. 15, 2023, and Taiwan application serial no. 112141904, filed on Nov. 1, 2023. The entirety of each of the above-mentioned patent applications is hereby incorporated by reference herein and made a part of this specification.

### BACKGROUND

### Technical Field

The disclosure relates to an electronic device, an in particular, relates to an electronic device not requiring a rotating sensor when detecting an object to be detected.

### Description of Related Art

Electronic devices (e.g., X-ray sensors) can be used in imaging of medical testing and/or non-destructive industrial testing. By applying the penetrating characteristics of X-ray, an X-ray sensor can perform detection without damaging an object to be detected. Therefore, X-ray is widely used in various fields such as personal biometric inspection, airport luggage or passenger security inspection, etc. However, the quality requirements for electronic devices are also increasing day by day.

### SUMMARY

The disclosure provides an electronic device that does not need to provide a rotating member to rotate a sensor when detecting an object to be detected, so that costs are lowered or the volume is decreased.

The disclosure provides an electronic device configured to detect an object to be detected. The electronic device includes at least one light source and a plurality of sensors. The at least one light source is arranged on a first plane and illuminates the object to be detected. The plurality of sensors are arranged on a second plane and surround the object to be detected. The plurality of sensors are stitched together. The first plane is different from the second plane.

In order to make the aforementioned and other features and advantages of the disclosure more comprehensible, several embodiments accompanied with figures are described in detail below.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic three-dimensional view of an electronic device according to a first embodiment of the disclosure.

FIG. 2 is a schematic side view of the electronic device of FIG. 1.

FIG. 3 is a schematic view of a sensor being unfolded in the electronic device of FIG. 1.

FIG. 4 is a cross-sectional schematic view of the sensor in the electronic device of FIG. 1.

FIG. 5 is a cross-sectional schematic view of the sensors in an electronic device according to a second embodiment of the disclosure.

FIG. 6 is a cross-sectional schematic view of sensors in an electronic device according to a third embodiment of the disclosure.

FIG. 7 is a cross-sectional schematic view of sensors of an electronic device according to a fourth embodiment of the disclosure.

FIG. 8 is a schematic three-dimensional view of an electronic device according to a fifth embodiment of the disclosure.

FIG. 9 is a schematic three-dimensional view of an electronic device according to a sixth embodiment of the disclosure.

### DESCRIPTION OF THE EMBODIMENTS

The accompanying drawings are included together with the detailed description provided below to provide a further understanding of the disclosure. Note that in order to make the drawings to be more comprehensible to readers and for the sake of clarity of the drawings, only part of the electronic device is depicted in the drawings of the disclosure, and specific elements in the drawings are not depicted according to actual scales. Moreover, the quantity and the size of each device in the drawings are only schematic and exemplary and are not intended to limit the scope of protection provided in the disclosure.

In the following specification and claims, the terminologies “containing”, “comprising”, etc. are open-ended terminologies, so they should be interpreted to mean “including but not limited to . . . ”.

It should be understood that when an element or a film layer is referred to as being “on” or “connected to” another element or film layer, it can be directly on the another element or film layer or be directly connected to the another element or film layer, or an inserted element or film layer may be provided therebetween (not a direct connection). In contrast, when the element is referred to as being “directly on” another element or film layer or “directly connected to” another element or film layer, an inserted element or film layer is not provided therebetween.

Although the terms “first”, “second”, “third” . . . may be used to describe various constituent elements, the constituent elements are not limited to these terms. These terms are only used to distinguish a single constituent element from other constituent elements in the specification. The same terms may not be used in the claims, and the elements in the claims may be replaced with first, second, third . . . according to the order declared by the elements in the claims. Therefore, in the following description, the first constituent element may be the second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, the meanings of “about”, “approximately”, “substantially”, and “roughly” may still be implied without specifying “about”, “approximately”, “substantially”, and “roughly”.

In some embodiments of the disclosure, regarding the words such as “connected”, “interconnected”, etc. referring to bonding and connection, unless specifically defined, these words mean that two structures are in direct contact or two structures are not in direct contact, and other structures are provided to be disposed between the two structures. The word for joining and connecting may also include the case where both structures are movable or both structures are fixed. In addition, the wordings “electrically connected” and “coupled” may include any direct or indirect electrical connection means. That is, when being referred to as being “electrically connected to another component (or a variation thereof)”, it can be directly connected to the other component or indirectly connected to the other component through one or more components.

In some embodiments of the disclosure, an optical microscopy (OM), a scanning electron microscope (SEM), a film thickness profile measuring instrument (α-step), an elliptical thickness measuring instrument, or other suitable methods may be adopted to measure the area, width, thickness, or height of each element or to measure the distance or spacing between elements. In detail, according to some embodiments, the scanning electron microscope may be used to obtain a cross-sectional structural image of an element to be measured, and to measure the area, width, thickness, or height of each element, or the distance or spacing between elements.

The electronic device of the disclosure may include but not limited to a display device, a backlight device, an antenna device, a sensing/detecting device, or a splicing device. The sensing device is, for example, an X-ray sensor or a fingerprint reader, but not limited thereto. In addition, the electronic device may include a bendable and flexible electronic device. The display device may be a non-self-luminous display device or a self-luminous display device. The electronic device may include but not limited to liquid crystal, a light emitting diode, fluorescence, phosphor, or a quantum dots (QDs), other suitable display media, or a combination of the foregoing. The antenna device may be a liquid crystal antenna device or a non-liquid crystal antenna device, and the sensing device may be a sensing device that senses capacitance, light, electromagnetic waves, heat, or ultrasound, but it is not limited thereto. In the disclosure, the electronic device may include an electronic element, and the electronic element may include a passive element and an active element, such as a capacitor, a resistor, an inductor, a diode, a transistor, a controller, a light-emitting unit, a photosensitive unit, a driving unit, an antenna unit, etc. The diode may include a light emitting diode (LED) or a photodiode. The LED may include but not limited to an organic LED (OLED), a sub-millimeter LED (mini LED), a micro LED, or a quantum dot LED. The splicing device may be, for example, a display splicing device or an antenna splicing device, but not limited thereto. Note that the electronic device may be any combination of the foregoing, but it is not limited thereto. The appearance of the electronic device may be rectangular, circular, polygonal, or a shape with curved edges, or other suitable shapes. The electronic device may have a peripheral system such as a driving system, a control system, a shelf system, etc. to support a display device, an antenna device, a wearable device (for example, including augmented reality or virtual reality), a vehicle-mounted device (for example, including a car windshield), a splicing device, or a sensing device. Hereinafter, an electronic device is provided herein to describe the content of the disclosure, but the disclosure is not limited thereto.

It should be understood that in the following embodiments, the features of several different embodiments may be replaced, recombined, and mixed to complete other embodiments without departing from the spirit of the disclosure. As long as the features of the embodiments do not violate the spirit of the disclosure or conflict each other, they may be mixed and matched as desired.

Descriptions of the disclosure are given with reference to the exemplary embodiments illustrated by the accompanying drawings. Wherever possible, the same reference numbers are used in the drawings and the description to refer to the same or like parts.

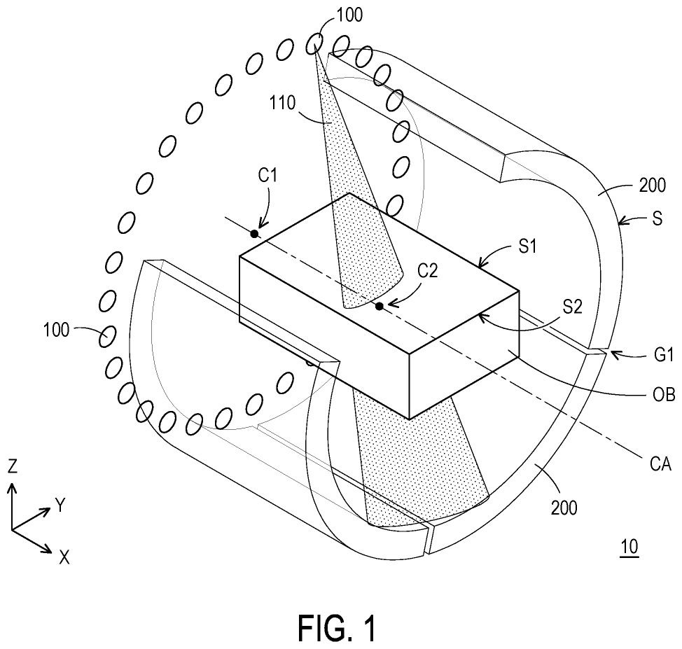

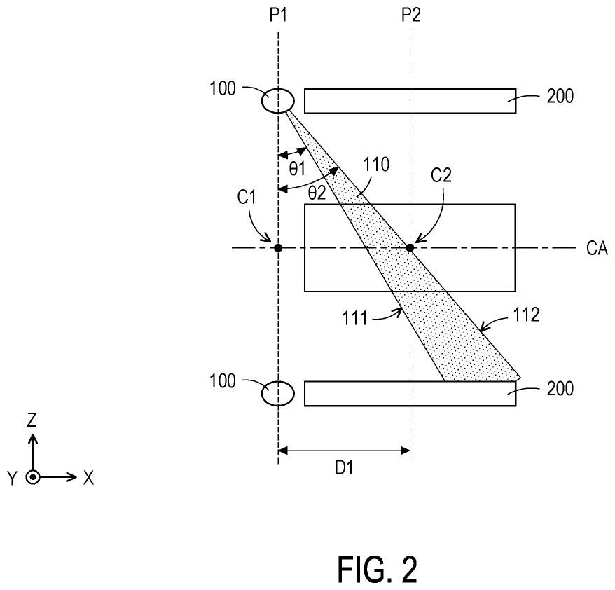

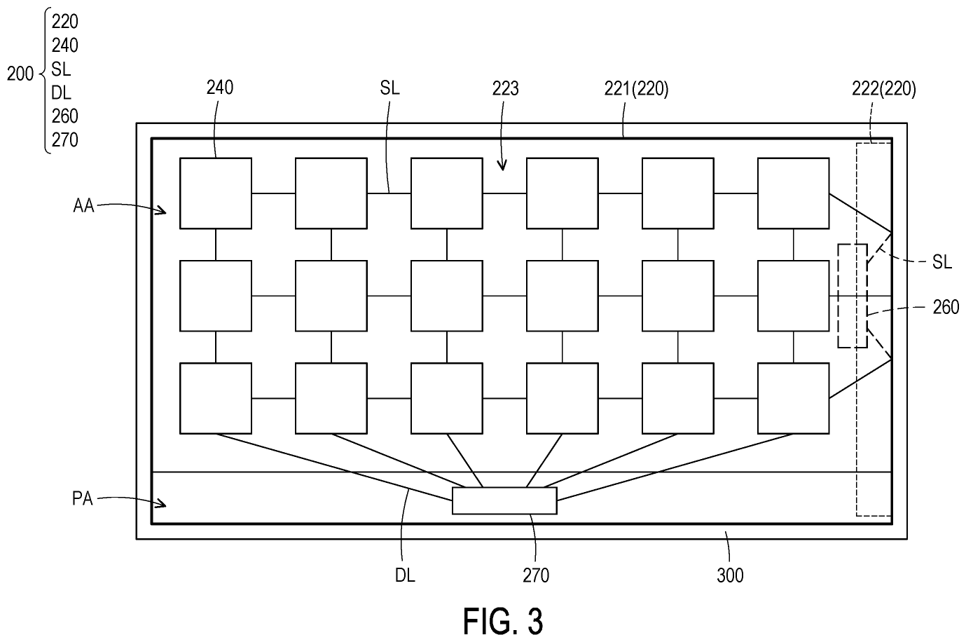

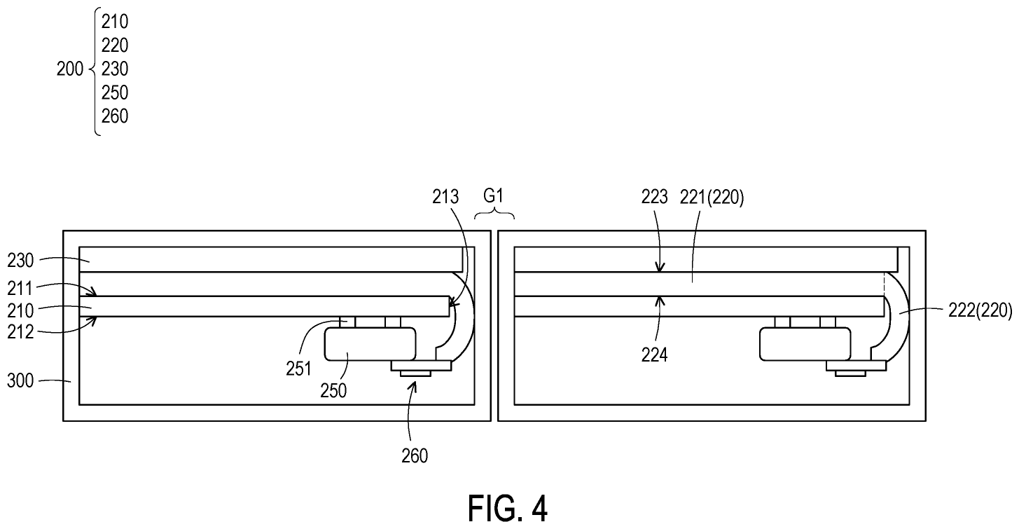

FIG. 1 is a schematic three-dimensional view of an electronic device according to a first embodiment of the disclosure. FIG. 2 is a schematic side view of the electronic device of FIG. 1. FIG. 3 is a schematic view of a sensor being unfolded in the electronic device of FIG. 1. FIG. 4 is a cross-sectional schematic view of the sensor in the electronic device of FIG. 1. For clarity of the accompanying drawings and ease of description, several elements in an electronic device 10 are omitted in FIG. 1 to FIG. 4.

With reference to FIG. 1 and FIG. 2 together, the electronic device 10 provided by this embodiment may include at least one light source 100 and a plurality of sensors 200. The electronic device 10 is configured to detect an object to be detected OB. Herein, the object to be detected OB may be but not limited to, for example, a human.

In this embodiment, a direction X, a direction Y, and a direction Z are different directions. For instance, the direction X is, for example, an extending direction of a long side S1 of the object to be detected OB in FIG. 1. The direction Y is, for example, an extending direction of a short side S2 of the object to be detected OB in FIG. 1. The direction Z is, for example, a normal direction of the electronic device 10 in FIG. 1 or a normal direction of the object to be detected OB. Herein, the direction X is substantially perpendicular to the direction Y, and the direction X and the direction Y are each substantially perpendicular to the direction Z, but it is not limited thereto.

To be specific, the light source 100 may be arranged on a first plane P1 formed by the direction Y and the direction Z, and the light source 100 may emit a light ray 110 to illuminate the object to be detected OB. Herein, when the light ray 110 is, for example, X-ray, since the X-ray has penetrability, the light ray 110 that illuminates the object to be detected OB may penetrate the object to be detected OB and illuminate the sensors 200. In this embodiment, an angle θ1 and an angle θ2 may be provided between the light ray 110 of the light source 100 that illuminates the object to be detected OB and the first plane P1, as shown in FIG. 2. Herein, the angle θ1 may be the angle between a first side 111 of the light ray 110 that is closest to the plane P1 and the plane P1, and the angle θ2 may be the angle between a second side 112 of the light ray 110 that is farthest from the plane P1 and the plane P1. In this embodiment, the angle θ1 may be greater than 0 degrees and less than 60 degrees (i.e., 0°<θ<60°), but it is not limited thereto. In some embodiments, the angle θ1 may also be greater than 3 degrees and less than 45 degrees (i.e., 3°<θ1<45°). Further, the angle θ2 may be the angle θ1 plus the desired appropriate size, so that the second side 112 of the light ray 110 penetrating the object to be detected OB may be as close as possible to an edge of the sensor 200 farthest from the plane P1, so as to maximize the use of a sensing area of the sensor 200 to detect all optical signals of the light ray 110 penetrating the object to be detected OB.

In this embodiment, the at least one light source 100 may be a plurality of light sources 100 (more than 27 are schematically shown in FIG. 1, but it is not limited thereto). The plurality of light sources 100 may be fixedly arranged on the first plane P1 individually, and the plurality of light sources 100 may be arranged in a circle on the first plane P1, but it is not limited thereto. In this embodiment, the plurality of light sources 100 may surround the object to be detected OB and have a surrounding center C1.

In this embodiment, the plurality of sensors 200 (three are schematically shown in FIG. 1, but it is not limited thereto) are fixedly arranged on a second plane P2 formed by the direction Y and the direction Z individually. The plurality of sensors 200 may surround the object to be detected OB and have a surrounding center C2. The plurality of sensors 200 may be used to detect the optical signal of the light ray 110 after penetrating the object to be detected OB to generate an electrical signal.

The plurality of sensors 200 may be stitched together, and a stitching gap G1 may be provided at a stitching position between two adjacent stitched sensors 200. Herein, the stitching gap G1 may be, for example, a minimum distance between one of the two adjacent sensors 200 and the other sensor 200. Besides, in this embodiment, “adjacent” means that there are no other identical elements between two identical elements.

The plurality of sensors 200 have bendable or flexible characteristics, and the plurality of sensors 200 may each be bent into an arc shape to have a curved surface S. In this embodiment, the plurality of curved sensors 200 may be stitched into a ¾ circle on the second plane P2, but it is not limited thereto. In some embodiments, the plurality of curved sensors may also be stitched into half a circle (i.e., a ½ circle) to a full circle.

In this embodiment, as shown in FIG. 2, the first plane P1 is different from the second plane P2, and the first plane P1 may be substantially parallel to the second plane P2, but it is not limited thereto. In this embodiment, a distance D1 may be provided between the first plane P1 and the second plane P2. Herein, the distance D1 is, for example, the distance measured in the direction X between the first plane P1 and the second plane P2.

With reference to FIG. 1 and FIG. 2 again, in an embodiment, the electronic device 10 may further include a central axis CA. The central axis CA may pass through the surrounding center C2 of the plurality of sensors 200 and the surrounding center Cl of the plurality of light sources 100. Herein, an extending direction of the central axis CA may be, for example, parallel to the direction X, but it is not limited thereto.

In this embodiment, when the electronic device 10 detects the object to be detected OB, the plurality of light sources 100 fixed at different positions on the first plane P1 may sequentially emit light 110 and illuminate the object to be detected OB. Next, the sensors 200 (e.g., the sensors 200 facing and misaligned with the light sources 100) fixed at corresponding positions on the second plane P2 detect the optical signal of the light ray 110 that penetrates the object to be detected OB and generate electrical signals. In this way, a plurality of image signals detected after the light sources 100 from different positions illuminate the object to be detected OB in different directions are obtained. Next, these image signals are reconstructed through other devices to create a three-dimensional image (3D image) of the object to be detected OB.

Therefore, compared to a conventional electronic device that requires a rotating member to rotate one light source and one sensor to obtain the image signals of the object to be detected being illuminated in different directions, the electronic device 10 provided by this embodiment may obtain the image signals of the object to be detected OB being illuminated in different directions by arranging the plurality of light sources 100 and sensors 200 surrounding the object to be detected OB. Therefore, expensive rotating members are not required to be arranged and/or precise angle control is not required to be performed, so that costs may be lowered or a volume of the electronic device may be decreased.

In addition, by arranging the plurality of light sources 100 and the plurality of sensors 200 on different planes, when a sensor 200 detects the light signal from the light ray 110 after the opposing light source 100 illuminates the object to be detected OB, the sensor 100 may not be blocked by another light source 100 that is adjacent to or overlaps with the sensor 200. Therefore, a more complete optical signal (or image signal) may be obtained, so that the three-dimensional image after image reconstruction may exhibit improved accuracy and may better reflect the real object to be detected OB.

With reference to FIG. 3 and FIG. 4 together, in this embodiment, the sensor 200 may include a support plate 210, a substrate 220, a scintillator 230, sensing units 240, a first signal line SL, a second signal line DL, a printed circuit board 250, a first driver 260, and a second driver 270.

As shown in FIG. 4, the support plate 210 has a first surface 211, a second surface 212, and a side surface 213. The first surface 211 and the second surface 212 are opposite to each other, and the side surface 213 connects the first surface 211 and the second surface 212. In this embodiment, the support plate 210 may be configured to support the substrate 220.

The substrate 220 is arranged on the first surface 211 of the support plate 210. The substrate 220 may include a first portion 221 and a second portion 222. The first portion 221 is arranged on the first surface 211 of the support plate 210, and the second portion 222 extends along the side surface 213 of the support plate 210 and is bent onto the second surface 212 of the support plate 210.

The substrate 220 has an upper surface 223 and a lower surface 224 that are opposite to each other, and the lower surface 224 is closer to the first surface 211 of the support plate 210 than the upper surface 223.

The substrate 220 has an active area AA and a peripheral area PA adjacent to the active area AA. A material of the substrate 220 may include but not limited to polycarbonate (PC), polyimide (PI), polyethylene terephthalate (PET), other suitable flexible substrate materials, or a combination of the foregoing.

The scintillator 230 is arranged on the upper surface 223 of the substrate 220. The scintillator 230 may overlaps the sensing units 240 in a normal direction of the substrate 220. The scintillator 230 may be used to, for example, convert the light ray 110 (e.g., X-ray) into visible light, but it is not limited thereto.

As shown in FIG. 3, the sensing units 240 are arranged on the upper surface 223 of the first portion 221 of the substrate 220. The sensing units 240 may, for example, be arranged in an array in the active area AA. The sensing units 240 may at least include a light detector (not shown) and a switching element (not shown). Herein, the light detector may be used to, for example, detect visible light and generate an electrical signal according to the intensity of the detected visible light signal (e.g., the number of photons of visible light). The switching element may be electrically connected to the light detector, so as to, for example, receive the electrical signal and transmit the electrical signal to other devices, but it is not limited thereto.

The first signal line SL is arranged on the first portion 221 and the upper surface 223 of the second portion 222 of the substrate 220. The first signal line SL is arranged in the active area AA. The first signal line SL may be electrically connected to the sensing units 240 and the first driver 260. The first signal line SL may be, for example, a scan line, but it is not limited thereto.

The second signal line DL is arranged on the upper surface 223 of the first portion 221 of the substrate 220. The second signal line DL may be arranged in the active area AA and the peripheral area PA. The second signal line DL may be electrically connected to the sensing units 240 and the second driver 270. The second signal line DL may be, for example, a data line, but it is not limited thereto.

As shown in FIG. 4, the printed circuit board 250 is arranged on the second surface 212 of the support plate 210. The printed circuit board 250 may be fixed to the second surface 212 of the support plate 210 through a fixing member 251. In this embodiment, the printed circuit board 250 may be, for example, a printed circuit board assembly (PCBA) or a flexible printed circuit board (FPC), and the fixing member 251 may be, for example, a stud, but it is not limited thereto.

The first driver 260 is arranged on the second portion 222 of the substrate 220, the first driver 260 may be arranged on the printed circuit board 250, and the first driver 260 is arranged on the second surface 212 of the support plate 210. The first driver 260 may be a chip-on-film (COF) and may include at least a circuit board and a driver chip. For instance, the first driver 260 may be a gate driver (gate on panel, GOP), but it is not limited thereto.

As shown in FIG. 3, the second driver 270 is arranged on the upper surface 223 of the first portion 221 of the substrate 220. The second driver 270 is arranged in the peripheral area PA. The second driver 270 may be a chip-on-film (COF) and may include at least a driver chip. For instance, the second driver 270 may be a source driver, but it is not limited thereto.

In this embodiment, the electronic device 10 may further include a plurality of housings 300, and the plurality of housings 300 may cover at least one sensor 200 among the plurality of sensors 200. For instance, as shown in FIG. 4, one housing 300 among the plurality of housings 300 may cover one sensor 200, but it is not limited thereto. In some embodiments, one housing may also cover two or more sensors 200. In this embodiment, a material of the housings 300 may include metal, carbon fiber reinforced polymer (CFRP), other suitable housing materials, or a combination of the foregoing, but it is not limited thereto.

In this embodiment, by bending the second portion 222 of the substrate 220 onto the second surface 212 of the support plate 210 and arranging the first driver 260 on the second portion 222 (or on the second surface 212 of the support plate 210), the active area AA of the substrate 220 may extend to the edge of the sensor 200 (i.e., the edge where the sensor 200 and another sensor 200 are stitched together) to achieve a narrow frame effect. In this way, when the sensor 200 and the another sensor 200 are stitched, the stitching gap G1 at the stitching position may also be decreased.

Other embodiments are described for illustration in the following. It should be noted that the reference numerals and a part of the contents in the previous embodiment are used in the following embodiments, in which identical reference numerals indicate identical or similar components, and repeated description of the same technical contents is omitted. Please refer to the description of the previous embodiments for the omitted content, which will not be repeated hereinafter.

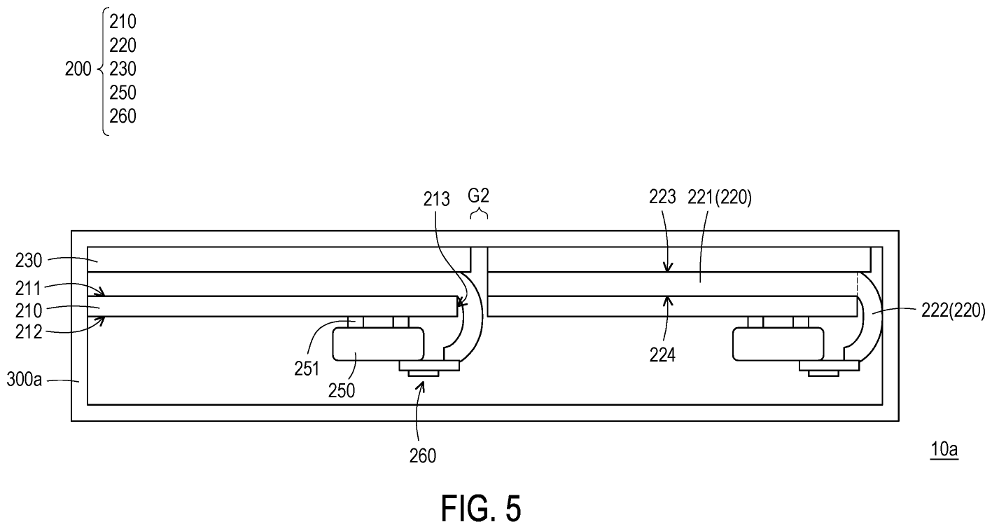

FIG. 5 is a cross-sectional schematic view of the sensors in an electronic device according to a second embodiment of the disclosure. With reference to FIG. 5 and FIG. 4 together, an electronic device 10a of this embodiment is similar to the electronic device 10 in FIG. 4, but the difference therebetween is that: in the electronic device 10a of this embodiment, a housing 300a may cover two sensors 200 together.

To be specific, with reference to FIG. 5, one housing 300a among the plurality of housings 300a may cover two sensors 200 together, and the two covered sensors 200 may be stitched together. In this embodiment, since there is no housing at the stitching position between the two sensors 200 covered by the housing 300a, a stitching gap G2 at the stitching position may be further decreased. In some embodiments that are not shown, the housing may also cover more than two sensors, and adjacent sensors may be stitched together.

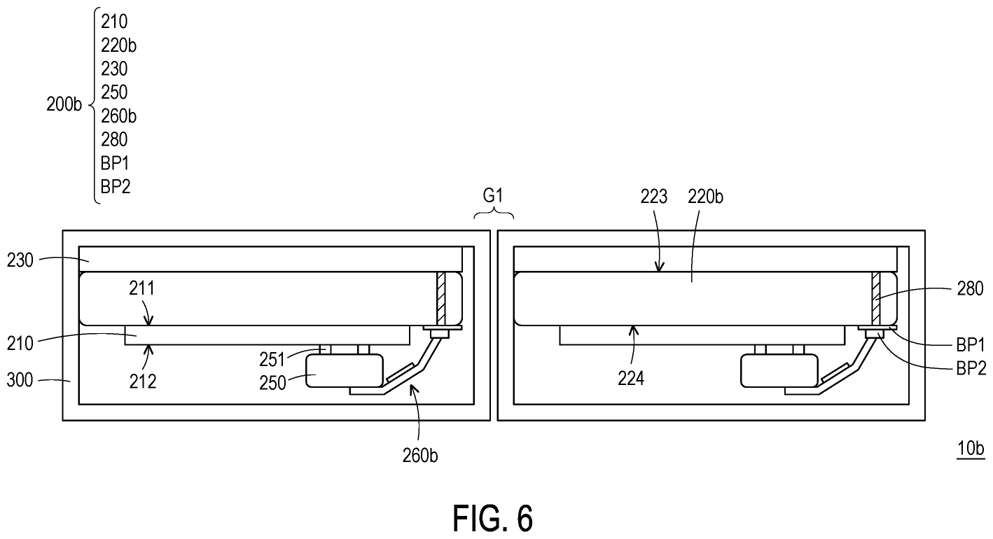

FIG. 6 is a cross-sectional schematic view of sensors in an electronic device according to a third embodiment of the disclosure. With reference to FIG. 6 and FIG. 4 together, an electronic device 10b of this embodiment is similar to the electronic device 10 in FIG. 4, but the difference therebetween is that: in the electronic device 10b of this embodiment, each of a plurality of sensors 200b further includes a conductive via 280, a bonding pad BP1, and a bonding pad BP2, and a substrate 220b does not need to be bent onto the second surface 212 of the support plate 210.

To be specific, with reference to FIG. 6, in this embodiment, the conductive via 280 may penetrate the substrate 220b, connect the upper surface 223 and the lower surface 224 of the substrate 220b, and electrically connect the sensing unit (not shown) and a first driver 260b.

The bonding pad BP1 is arranged on the lower surface 224 of the substrate 220b, and the bonding pad BP1 may contact the conductive via 280. The bonding pad BP2 may connect the bonding pad BP1 and the first driver 260b. In this embodiment, the first driver 260b may be electrically connected to the sensing unit through the bonding pad BP2, the bonding pad BP1, the conductive via 280, and the first signal line (not shown).

In this embodiment, by arranging the first driver 260b on the second surface 212 of the support plate 210 and allowing the first driver 260b to be electrically connected to the sensing unit through the conductive via 280, the active area of the substrate 220b may extend to the edge of the sensor (i.e., the edge where the sensor and another sensor are stitched) to achieve a narrow frame effect. In this way, when the sensor and the another sensor are stitched, the stitching gap G1 at the stitching position may also be decreased.

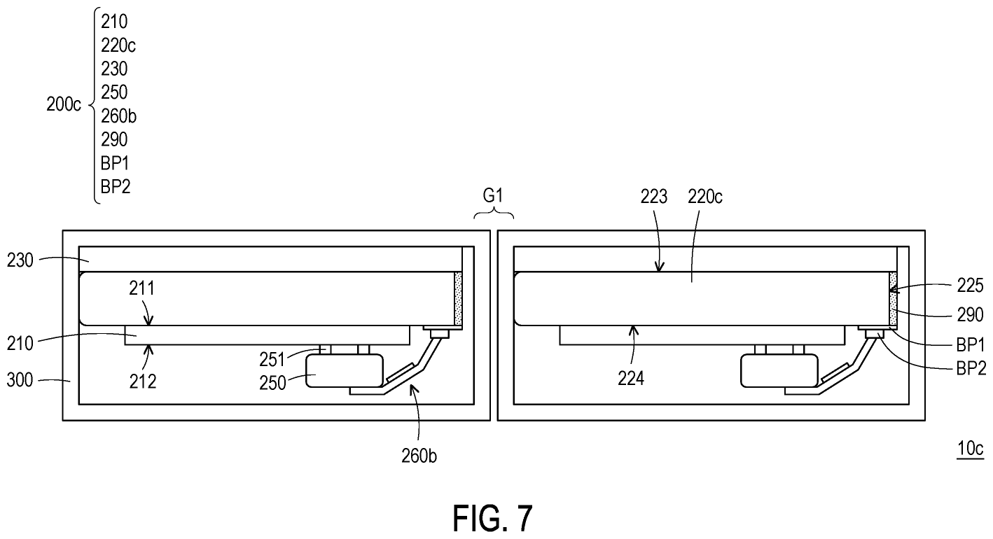

FIG. 7 is a cross-sectional schematic view of sensors of an electronic device according to a fourth embodiment of the disclosure. With reference to FIG. 7 and FIG. 6 together, an electronic device 10c of this embodiment is similar to the electronic device 10b in FIG. 6, but the difference therebetween is that: in the electronic device 10c of this embodiment, each of a plurality of sensors 200c further includes conductive glue 290.

To be specific, with reference to FIG. 7, a substrate 220c has the upper surface 223, the lower surface 224, and a side surface 225. The upper surface 223 and the lower surface 224 are opposite to each other, and the side surface 225 may connect the upper surface 223 and the lower surface 224.

The conductive glue 290 is arranged on the side surface 225 of the substrate 220c and may connect the upper surface 223 and the lower surface 224 of the substrate 220c. The conductive glue 290 may contact the bonding pad BP1. In this embodiment, the conductive glue 290 may replace the conductive via 280 in FIG. 6 to electrically connect the sensing unit (not shown) and the first driver 260b.

In this embodiment, by arranging the first driver 260b on the second surface 212 of the support plate 210 and allowing the first driver 260b to be electrically connected to the sensing unit through the conductive glue 290, the active area of the substrate 220c may extend to the edge of the sensor (i.e., the edge where the sensor and another sensor are stitched) to achieve a narrow frame effect. In this way, when the sensor and the another sensor are stitched, the stitching gap G1 at the stitching position may also be decreased.

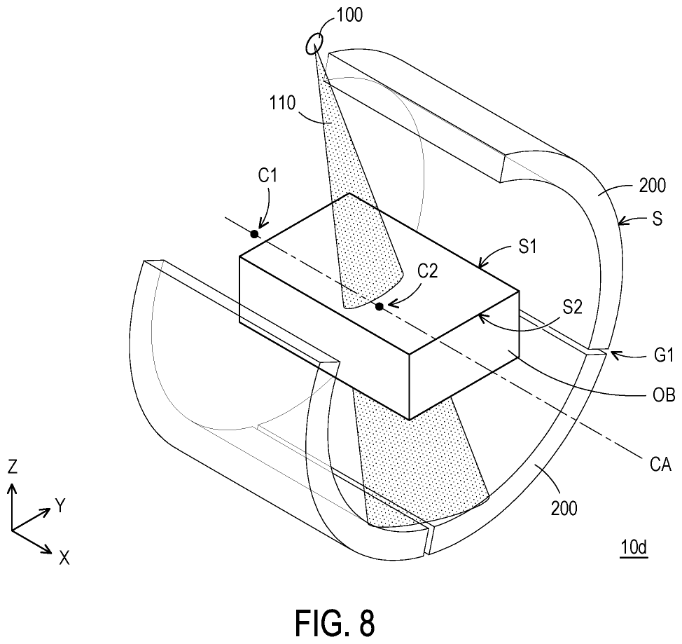

FIG. 8 is a schematic three-dimensional view of an electronic device according to a fifth embodiment of the disclosure. With reference to FIG. 8 and FIG. 1 together, an electronic device 10d of this embodiment is similar to the electronic device 10 in FIG. 1, but the difference therebetween is that: in the electronic device 10d of this embodiment, there is only one light source 100.

To be specific, with reference to FIG. 8, one light source 100 may be, for example, a rotatable tube source that can rotate around the central axis CA. Therefore, when the electronic device 10d of this embodiment detects the object to be detected OB, the light source 100 may rotate around the central axis CA.

In this embodiment, when the electronic device 10d detects the object to be detected OB, the light source 100 rotated to a different position on the first plane P1 can emit the light ray 110 and illuminate the object to be detected OB. Next, the sensors 200 (e.g., the sensors 200 facing and misaligned with the light source 100) fixed at corresponding positions on the second plane P2 detect the optical signal of the light ray 110 that penetrates the object to be detected OB and generate electrical signals. In this way, a plurality of image signals detected after the light source 100 rotated to different positions illuminate the object to be detected OB in different directions are obtained. Next, these image signals are reconstructed through other devices to create a three-dimensional image of the object to be detected OB.

Therefore, compared to a conventional electronic device that requires a rotating member to rotate one light source and one sensor to obtain the image signals of the object to be detected being illuminated in different directions, the electronic device 10d provided by this embodiment may obtain the image signals of the object to be detected OB being illuminated in different directions by arranging one rotatable light source 100 and the plurality of sensors 200 surrounding the object to be detected OB. Therefore, expensive rotating members are not required to be arranged to rotate the sensors 200, so that costs may be lowered or the volume of the electronic device is decreased.

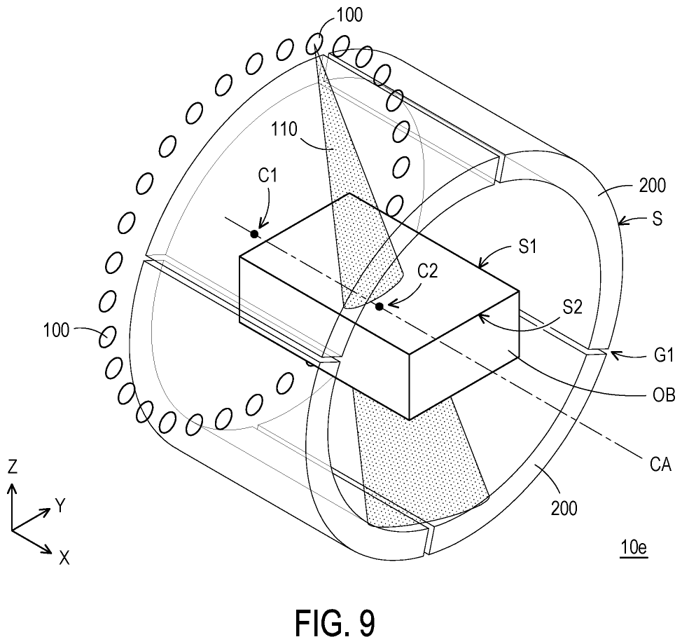

FIG. 9 is a schematic three-dimensional view of an electronic device according to a sixth embodiment of the disclosure. With reference to FIG. 9 and FIG. 4 together, an electronic device 10e of this embodiment is similar to the electronic device 10 in FIG. 4, but the difference therebetween is that: in the embodiment 10e of this electronic device, the plurality of sensors 200 may be stitched into a complete circle to form a structure that can surround the entire object to be detected OB. In this way, the electronic device 10e of this embodiment may obtain the image signals of the object to be detected OB illuminated by different light sources 100 in different directions through the structure of the plurality of sensors 200 surrounding the entire object to be detected OB. In this way, through these more complete image signals, the three-dimensional image of the object to be detected OB after image reconstruction may exhibit improved accuracy or may better reflect the real object to be detected OB.

In view of the foregoing, in the electronic device provided by an embodiment of the disclosure, by arranging the plurality of light sources and sensors to surround the object to be detected to obtain the image signals of the object to be detected being illuminated in different directions, expensive rotating members are not required to be arranged and/or precise angle control is not required to be performed, so that costs may be lowered or the volume of the electronic device may be decreased. By arranging the plurality of light sources and the plurality of sensors on different planes, when a sensor detects the light signal from the light ray after the opposing light source illuminates the object to be detected, the sensor may not be blocked by another light source that is adjacent to or overlaps with the sensor. Therefore, a more complete optical signal (or image signal) may be obtained, so that the three-dimensional image after image reconstruction may exhibit improved accuracy and may better reflect the real object to be detected.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device configured to detect an object to be detected, comprising:
at least one light source arranged on a first plane and illuminating the object to be detected; and
a plurality of sensors arranged on a second plane and surrounding the object to be detected, wherein the plurality of sensors are stitched together,
wherein the first plane is different from the second plane.

2. The electronic device according to claim 1, wherein the first plane is parallel to the second plane.

3. The electronic device according to claim 1, wherein a distance is provided between the first plane and the second plane.

4. The electronic device according to claim 1, wherein each of the plurality of sensors comprises:
a support plate having a first surface, a second surface, and a side surface;
a substrate arranged on the first surface;
a sensing unit arranged on the substrate; and
a scintillator arranged on the substrate.

5. The electronic device according to claim 4, wherein the substrate comprises a first portion and a second portion, the first portion is arranged on the first surface, the second portion extends along the side surface and is bent onto the second surface, and each of the plurality of sensors further comprises:
a first signal line arranged on the first portion and the second portion; and
a first driver arranged on the second portion,
wherein the sensing unit is arranged on the first portion.

6. The electronic device according to claim 5, wherein the first signal line is electrically connected to the sensing unit and the first driver.

7. The electronic device according to claim 4, wherein each of the plurality of sensors further comprises:
a first driver arranged on the second surface of the support plate; and
a conductive via penetrating the substrate and electrically connected to the sensing unit and the first driver.

8. The electronic device according to claim 7, wherein each of the plurality of sensors further comprises:
a first signal line arranged on the substrate and electrically connected to the sensing unit and the conductive via.

9. The electronic device according to claim 4, wherein each of the plurality of sensors further comprises:
a first driver arranged on the second surface of the support plate; and
conductive glue arranged on a side surface of the substrate and electrically connected to the sensing unit and the first driver.

10. The electronic device according to claim 9, wherein each of the plurality of sensors further comprises:
a first signal line arranged on the substrate and electrically connected to the sensing unit and the conductive glue.

11. The electronic device according to claim 4, wherein each of the plurality of sensors further comprises:
a printed circuit board arranged on the second surface of the support plate.

12. The electronic device according to claim 4, wherein each of the plurality of sensors further comprises:
a second signal line arranged on the substrate; and
a second driver arranged on the substrate and electrically connected to the sensing unit through the second signal line.

13. The electronic device according to claim 4, wherein each of the plurality of sensors further comprises:
a housing covering at least one of the plurality of sensors.

14. The electronic device according to claim 1, wherein the plurality of sensors are stitched to form half a circle to a full circle.

15. The electronic device according to claim 1, further comprising:
a central axis passing through a surrounding center of the plurality of sensors,
wherein the at least one light source is one light source, and the light source rotates around the central axis.

16. The electronic device according to claim 1, wherein the at least one light source is a plurality of light sources, and the plurality of light sources surround the object to be detected.

17. The electronic device according to claim 16, wherein the plurality of X-ray sources are arranged in a circle on the first plane.

18. The electronic device according to claim 1, wherein an angle is provided between a light ray of the at least one light source illuminating the object to be detected and the first plane.

19. The electronic device according to claim 1, wherein the angle is greater than 0 degrees and less than 60 degrees.

20. The electronic device according to claim 1, wherein a light ray emitted by the at least one light source penetrates through the object to be detected and illuminates the plurality of sensors.
